(19) United States
(12) Patent Application Publication
(10) Pub. No.: US 2024/0401237 A1
(43) Pub. Date: Dec. 5, 2024

(54) METHOD FOR PREPARING DIRECTIONALLY SOLIDIFIED TiAl ALLOY

(71) Applicant: University of Science and Technology Beijing, Beijing (CN)

(72) Inventors: Yongfeng Liang, Beijing (CN); Fuqiang Zhang, Beijing (CN); Junpin Lin, Beijing (CN); Leming Xu, Beijing (CN); Gang Yang, Beijing (CN); Xianfei Ding, Beijing (CN)

(73) Assignee: University of Science and Technology Beijing, Beijing (CN)

(21) Appl. No.: 18/609,883

(22) Filed: Mar. 19, 2024

(30) Foreign Application Priority Data
Jun. 1, 2023 (CN) 202310640388.0

(51) Int. Cl. C30B 29/52; C30B 15/10; C30B 15/14; C30B 15/20; C30B 29/66

(52) U.S. Cl. CPC C30B 29/52; C30B 15/10; C30B 15/14; C30B 15/20; C30B 29/66

(57) ABSTRACT

Disclosed is a method for preparing a directionally solidified TiAl alloy, including: (1) melting and casting a master alloy to obtain a TiAl alloy ingot; (2) processing the TiAl alloy ingot into a sample rod, and placing the sample rod into a refractory metal crucible and then assembling the refractory metal crucible to a directional solidification furnace; (3) vacuumizing the directional solidification furnace, and heating the directional solidification furnace to gradually raise a temperature to exceed a melting point of the sample rod, and conducting heat preservation to melt the sample rod uniformly to obtain a molten TiAl alloy; and (4) directionally pulling the molten TiAl alloy after the heat preservation to allow directional growth to a growth length, stopping the directionally pulling, and taking out an obtained sample to obtain a test rod of the directionally solidified TiAl.

### CROSS REFERENCE TO RELATED APPLICATION

This patent application claims the benefit and priority of Chinese Patent Application No. 202310640388.0 filed with the China National Intellectual Property Administration on Jun. 1, 2023,the disclosure of which is incorporated by reference herein in its entirety as part of the present application.

### TECHNICAL FIELD

The present disclosure belongs to the technical field of metal material preparation, and particularly relates to a method for preparing a directionally solidified TiAl alloy.

### BACKGROUND

TiAl-based alloys are considered to be the most potential high-temperature structural materials due to light weight, high specific strength and stiffness, and excellent high-temperature comprehensive mechanical properties, and are expected to be used in aerospace, automotive engines and other fields. TiAl alloys with Nb can significantly improve the yield strength and high-temperature oxidation resistance, thus showing comprehensive mechanical properties better than those of the ordinary TiAl alloys. The development of Nb—TiAl alloys has become a hot spot in TiAl alloy studies at home and abroad.

As an intermetallic compound, the TiAl alloy is mainly limited in engineering applications by its intrinsic brittleness at room temperature and difficulty in processing. Mechanical properties of the TiAl alloy are closely related to its structure. Studies have shown that fully lamellar structure shows better high-temperature strength and fracture toughness compared with other structures. Also, the strength and plasticity of the TiAl alloy with a fully lamellar structure are related to the load direction, exhibiting strong anisotropy. On one hand, a uniform and fine fully lamellar equiaxed crystal structure obtained by deformation and phase transformation is a traditional method for improving the microstructure and properties of TiAl alloys. However, these methods consume high energy and has limited improvement in room-temperature plasticity. On the other hand, a directional solidification is used for controlling the heat transfer direction to establish a unidirectional temperature gradient in the crystal growth direction and achieve a stable growth of columnar crystals, thereby eliminating cross grain boundaries and allowing the best comprehensive mechanical properties of the TiAl alloys. Studies have shown that TiAl alloys with consistent lamellar orientations prepared by directional solidification have room-temperature plasticity and high-temperature comprehensive properties that exceed those of equiaxed crystals. The TiAl alloys also show great potential and broad prospects in the engineering applications.

TiAl alloy has a high melting point and strong reactivity, and can undergo interfacial reactions with almost all traditional metal oxide crucibles, including those prepared from alumina, boron nitride, etc. In view of this, not only alloy compositions are changed during the directional solidification, but also the shaping of the alloys can be affected, thus greatly damaging their mechanical properties. Yttria, as a relatively stable ceramic crucible material, is generally considered to be a shell mold material for the TiAl alloy casting. However, the bulk yttria is difficult to form a dense structure. Melt is in contact with the crucible wall for a long time during the directional heat preservation, and the heat flow scouring causes yttria particles to enter the melt at a size reaching a micron level. Oxide particles can act as crack sources during the deformation process, causing the alloy to fail prematurely. In addition, the oxide ceramic crucibles inevitably introduce oxygen element into the melt. The oxygen element leads to a significant deterioration of the mechanical properties of the TiAl alloys. Therefore, there is an urgent need to develop a novel non-polluting crucible for directional solidification of the TiAl alloys.

Compared with skull melting process and optical floating zone method, the directional solidification based on Bridgman method has low energy consumption, large sample size, near net shape, etc., which is a method with the most engineering application prospect. This method is also commonly used in the production of single crystals of the superalloys. Induction heating can control the heating temperature and position to ensure the length of the melting zone, which is not available in resistive heating methods. Accordingly, it is of an important engineering application value to develop a method for preparing a non-polluting directional solidification under existing conditions and technology accumulation.

### SUMMARY

An object of the present disclosure is to provide a method for preparing a directionally solidified TiAl alloy without inclusion. The preparation method successfully achieves a directional solidification of a TiAl alloy by using a refractory metal crucible instead of a traditional ceramic crucible and improving directional solidification parameters, thereby obtaining a directional sample of a high-purity TiAl alloy without oxide inclusions. The preparation method has a simple and reliable processing technology and an excellent directional microstructure performance.

In order to solve the above mentioned technical problems, the present disclosure adopts the following technical solutions:

The present disclosure provides a method for preparing a directionally solidified TiAl alloy, including the following steps:
(1) melting a master alloy: melting and casting the master alloy by induction skull melting (ISM) to obtain a TiAl alloy ingot;
(2) processing the TiAl alloy ingot obtained in step (1) into a sample rod, polishing a surface of the sample rod with a sandpaper until the surface is bright, and placing the sample rod into a refractory metal crucible and then assembling the refractory metal crucible to a directional solidification furnace;
(3) vacuumizing the directional solidification furnace, introducing high-purity argon into the directional solidification furnace, turning on a high-frequency induction power supply and heating the directional solidification furnace to gradually raise a temperature of the directional solidification furnace to exceed a melting point of the sample rod, stopping heating, and conducting heat preservation to melt the sample rod uniformly to obtain a molten TiAl alloy; and
(4) directionally pulling the molten TiAl alloy after the heat preservation to allow directional growth, stopping the directionally pulling after reaching a growth length, cooling, introducing air, taking out an obtained sample, and removing a reaction layer on a surface of the sample by machining to obtain a test rod of the directionally solidified TiAl alloy.

In some embodiments, the TiAl alloy ingot in step (1) has a composition of (47-54)Ti-(45-48) Al-(1-5)Nb-(0-0.6)C, namely has a composition, by atomic percentages, of 47% to 54% of Ti, 45% to 48% of Al, 1% to 5% of Nb, and 0% to 0.6% of C.

In some embodiments, the sample rod in step (2) has a dimension of Φ (5-50) mm×120 mm.

In some embodiments, the refractory metal crucible in step (2) is prepared from a material selected from the group consisting of pure niobium, pure molybdenum, and pure tungsten. An inner diameter of the refractory metal crucible is slightly larger than that of the sample rod, and the refractory metal crucible has a wall thickness of 0.1 mm to 5 mm.

In some embodiments, in step (3), the directional solidification furnace is vacuumized to 6×10⁻³ Pa by using a two-stage vacuum pump including a mechanical pump and a molecular pump, the two-stage vacuum pump is turned off, and then the high-purity argon is introduced into a cavity to 500 Pa.

In some embodiments, in step (3), a power of the directional solidification furnace is controlled such that a temperature of a melting zone of the sample rod does not exceed the melting point of the sample rod by 50° C., and a length of the melting zone of the sample rod is no more than 15 mm. In some embodiments, the heat preservation is conducted for 30 min to 60 min, resulting in a uniform temperature field distribution in the cross section while maintaining a stable temperature gradient along the longitudinal direction. A dissolved amount of metal elements in the crucible by reaction is controlled by controlling a contact time between the melt and the crucible.

In some embodiments, in step (4), the directionally pulling is controlled at a speed of 10 μm/s to 160 μm/s by using a programmable logic controller (PLC) panel, which ensures the stable growth of columnar dendrites.

In some embodiments, in step (4), a motor movement is stopped after the growth length reaches 120 mm, the high-frequency induction power supply is turned off, and the sample is cooled to room temperature by furnace cooling.

Compared with the prior art, some embodiments of the present disclosure have the following significant advantages:

1. In the present disclosure, the non-pollution preparation process of the directionally solidified TiAl alloy avoids the entry of particles that would destroy mechanical properties, thus completely eliminating the pollution of oxide ceramic crucible to the alloy 2. In the present disclosure, the preparation method greatly inhibits the increase of oxygen element during the directional solidification of the alloys, and significantly improves the mechanical properties of the directionally solidified TiAl alloys. When refractory metals such as Nb, Mo, and W are used in the crucibles and contact with TiAl alloy melt, part of the metals may be dissolved by diffusion reaction, with a limited dissolution amount; while dissolved Nb, Mo, and W can be used as alloying elements of the TiAl alloy, which are beneficial and harmless. On the basis of controlling the increments of Nb, Mo, W, etc. in the directional solidification process, designing the raw materials for the directional solidification and controlling the parameters during the directional solidification can achieve an expected composition of directionally solidified TiAl alloy without pollution. Since the induction heating has certain convective stirring effect on the TiAl alloy liquid, the composition of the refractory metal elements dissolved by the reaction is basically the same at the edge of and in the center of a resulting casting rod after the directional solidification. The preparation method has simple and reliable operations, low equipment energy consumption, outstanding directional solidification effect, universal applicability, and practical engineering application values.

### BRIEF DESCRIPTION OF THE DRAWINGS

In order to describe the technical solutions in the examples of the present disclosure more clearly, the accompanying drawings required to describe the examples are briefly described below. Apparently, the accompanying drawings described below are only some examples of the present disclosure. Those of ordinary skill in the art may further obtain other accompanying drawings based on these accompanying drawings without inventive labour.

FIG. 1 shows an appearance diagram of a refractory metal crucible;

FIG. 2 shows a microstructure of a longitudinal section of the directionally solidified PST crystal sample of Ti-44Al-8Nb-0.5C (raw materials: Ti-46Al-4Nb-0.5C) prepared in Example 2;

FIG. 3 shows a microstructure of a cross-section of the alloy in FIG. 2;

FIG. 4 shows a dendrite morphology diagram of a cross-section of a mushy zone of the Ti-46Al-7Nb alloy (raw materials: Ti-48Al-5Nb) prepared in Example 4;

FIG. 5 shows a dendrite orientation distribution diagram of the alloy in FIG. 4;

FIG. 6 shows a microstructure of a longitudinal section of the directionally solidified PST crystal sample of Ti-46Al-4Nb-0.5C prepared in Comparative Example 1;

FIG. 7 shows a high-magnification appearance of the structure in FIG. 6; and

FIG. 8 shows a comparison of room-temperature tensile properties of the directional structures of the alloys obtained in Example 2 and Comparative Example 1.

### DETAILED DESCRIPTION OF THE EMBODIMENTS

The technical solutions and technical problems solved in the embodiments of the present disclosure will be described below in conjunction with the examples of the present disclosure. Apparently, the described examples are merely a part rather than all of the examples of the present disclosure.

A master alloy with a composition, by atomic percentages, of (47-54)Ti-(45-48)Al-(1-5)Nb-(0-0.6)C was casted to obtain an ingot through ISM, and then the ingot was cut into a sample rod of (Φ(5-50) mm×120 mm) by machining. The sample rod was subjected to directional solidification, which was performed as follows:

### Example 1

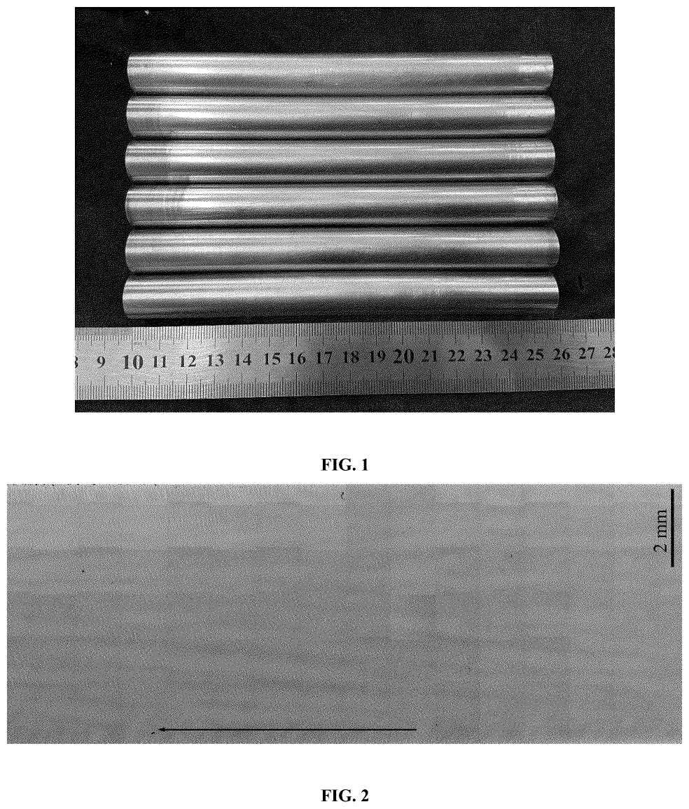

A surface of a sample rod with a composition of Ti-47Al-5Nb was polished brightly while removing machining traces, and then the sample rod was placed into a pure molybdenum crucible with a wall thickness of 0.3 mm, where an appearance of the crucible is shown in FIG. 1. The sample rod and the crucible were installed on a pull-out base in a Bridgman directional solidification furnace. A furnace cavity was closed and vacuumized to 6×10⁻³ Pa by using a vacuumizing system. The vacuumizing system was turned off, and the cavity was filled with high-purity argon to 500 Pa. A high-frequency induction power supply was turned on, and heating was conducted to gradually raise to a temperature of 1,720° C. Heat preservation was conducted at the temperature for 30 min to make the alloy melt evenly; a pulling speed was set on a PLC panel to 10 μm/s, and the movement was stopped after the sample rod moved 120 mm; the power supply was turned off and the sample rod was cooled for 30 min, and then the cavity was opened to take out a directionally solidified sample, and a surface layer on the sample was removed. The resulting directionally solidified test rod has a chemical composition of Ti-45Al-5Nb-3Mo.

### Example 2

A surface of a sample rod with a composition of Ti-46Al-4Nb-0.5C was polished brightly while removing machining traces, and then the sample rod was placed into a pure niobium crucible with a wall thickness of 1 mm. The sample rod and the crucible were installed on a pull-out base in a Bridgman directional solidification furnace. A furnace cavity was closed and vacuumized to 6×10⁻³ Pa by using a vacuumizing system. The vacuumizing system was turned off, and the cavity was filled with high-purity argon to 500 Pa. A high-frequency induction power supply was turned on, and heating was conducted to gradually raise to a temperature of 1,720° C. Heat preservation was conducted at the temperature for 30 min to make the alloy melt evenly; a pulling speed was set on a PLC panel to 50 μm/s, and the movement was stopped after the sample rod moved 120 mm; the power supply was turned off and the sample rod was cooled for 30 min, and then the cavity was opened to take out a directionally solidified sample, and a surface layer on the sample was removed. The resulting directionally solidified test rod has a chemical composition of Ti-44Al-8Nb-0.5C.

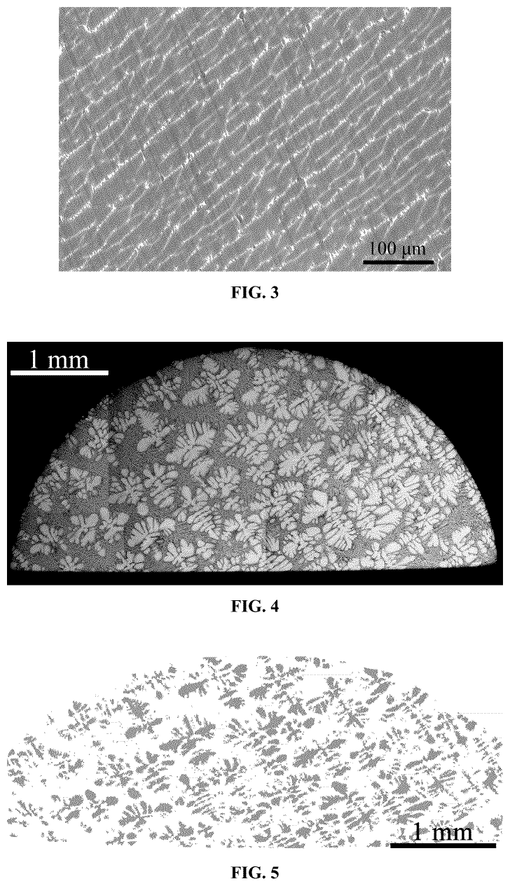

FIG. 2 shows a microstructure of a longitudinal section of the directionally solidified PST crystal sample prepared with a pure niobium crucible. It can be seen from the figure that the lamellar direction of the PST crystal was consistent with the growth direction, and there are no oxide inclusions inside. Due to dissolution of metal elements in the crucible by reaction, the directional structure composition is Ti-44Al-8Nb-0.5C. FIG. 3 shows a microstructure of a cross-section of the alloy in FIG. 2. The alloy was mainly composed of a α₂/γ lamellae and residual B2 phase evenly distributed in the lamellae, and the orientation of the lamellae remains consistent.

### Example 3

A surface of a sample rod with a composition of Ti-48Al-1.5Nb-0.2C was polished brightly while removing machining traces, and then the sample rod was placed into a pure niobium crucible with a wall thickness of 3 mm. The sample rod and the crucible were installed on a pull-out base in a Bridgman directional solidification furnace. A furnace cavity was closed and vacuumized to 6×10⁻³ Pa by using a vacuumizing system. The vacuumizing system was turned off, and the cavity was filled with high-purity argon to 500 Pa. A high-frequency induction power supply was turned on, and heating was conducted to gradually raise to a temperature of 1,720° C. Heat preservation was conducted at the temperature for 30 min to make the alloy melt evenly; a pulling speed was set on a PLC panel to 160 μm/s, and the movement was stopped after the sample rod moved 120 mm; the power supply was turned off and the sample rod was cooled for 30 min, and then the cavity was opened to take out a directionally solidified sample, and a surface layer on the sample was removed. The resulting directionally solidified test rod has a chemical composition of Ti-46.5Al-4Nb-0.2C.

### Example 4

A surface of a sample rod with a composition of Ti-48Al-5Nb was polished brightly while removing machining traces, and then the sample rod was placed into a pure niobium crucible with a wall thickness of 2 mm. The sample rod and the crucible were installed on a pull-out base in a Bridgman directional solidification furnace. A furnace cavity was closed and vacuumized to 6×10⁻³ Pa by using a vacuumizing system. The vacuumizing system was turned off, and the cavity was filled with high-purity argon to 500 Pa. A high-frequency induction power supply was turned on, and heating was conducted to gradually raise a temperature of 1,720° C. Heat preservation was conducted at the temperature for 30 min to make the alloy melt evenly; a pulling speed was set on a PLC panel to 120 μm/s, and the movement was stopped after the sample rod moved 50 mm, the sample rod was quenched in a metal liquid rapidly; the power supply was turned off and the sample rod was cooled for 30 min, and then the cavity was opened to take out a directionally solidified sample, and a surface layer on the sample was removed. The resulting directionally solidified test rod has a chemical composition of Ti-46Al-7Nb.

FIG. 4 shows a dendrite morphology diagram of a cross-section of a mushy zone of the Ti-48Al-5Nb alloy, and FIG. 5 shows an orientation distribution figure of the dendrites of the alloy in FIG. 4. It can be seen that the dendrites orientation is consistent, and the PST crystals are formed during the cooling. This was mainly caused by the rapid quenching and then cooling with furnace after pulling.

### Comparative Example 1

A surface of a sample rod with a composition of Ti-46Al-4Nb-0.5C was polished brightly while removing machining traces, and then the sample rod was placed into a high-purity yttria oxide crucible with a wall thickness of 1 mm. The sample rod and the crucible were installed on a pull-out base in a Bridgman directional solidification furnace. A furnace cavity was closed and vacuumized to 6×10⁻³ Pa by using a vacuumizing system. The vacuumizing system was turned off, and the cavity was filled with high-purity argon to 500 Pa. A high-frequency induction power supply was turned on, and heating was conducted to gradually raise a temperature of 1,720° C. Heat preservation was conducted at the temperature for 30 min to make the alloy melt evenly; a pulling speed was set on a PLC panel to 50 μm/s, and the movement was stopped after the sample rod moved 120 mm; the power supply was turned off and the sample rod was cooled for 30 min, and then the cavity was opened to take out a directionally solidified sample, and a surface layer on the sample was removed.

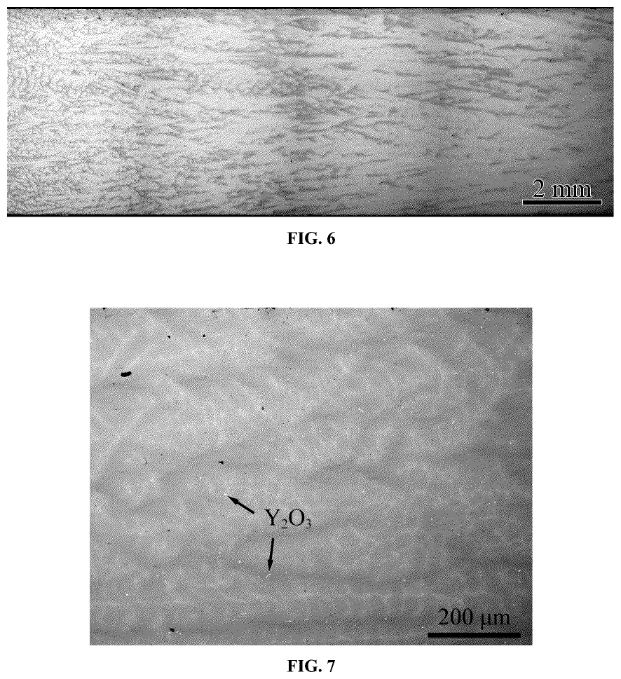

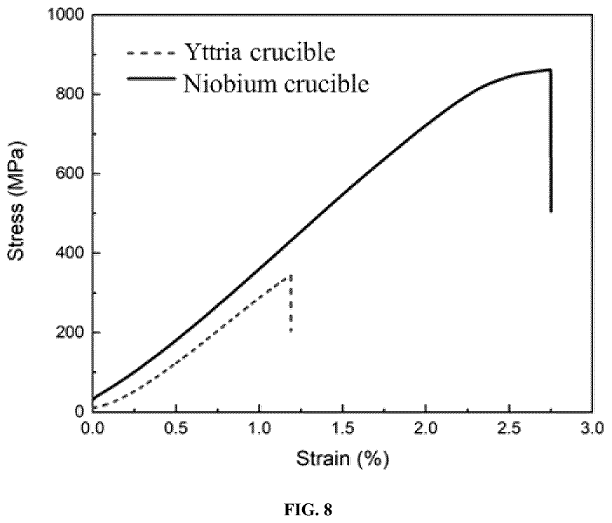

FIG. 6 shows a microstructure of a longitudinal section of the directionally solidified PST crystal sample of Ti-46Al-4Nb-0.5C prepared in Comparative Example 1 with the high-purity yttria crucible, and there are obvious white yttria particles in the lamellae. FIG. 7 shows a high-magnification appearance of the microstructure in FIG. 6, and white yttria particles are dispersed in the lamellae. FIG. 8 shows a comparison of room-temperature tensile properties of the directional structures of the alloys obtained in Example 2 and Comparative Example 1, and the strength and plasticity of the directional solidification structure prepared with metal crucibles far exceed that with the yttria crucible.

The foregoing are descriptions of the preferred embodiments of the present disclosure. It should be noted that a person of ordinary skill in the art can make several improvements and modifications without departing from the principle of the present disclosure, and such improvements and modifications should be deemed as falling within the scope of the present disclosure.

1. A method for preparing a directionally solidified TiAl alloy, comprising the following steps:
(1) melting a master alloy: melting and casting the master alloy by induction skull melting to obtain a TiAl alloy ingot;
(2) processing the TiAl alloy ingot obtained in step (1) into a sample rod, polishing a surface of the sample rod with a sandpaper until the surface is bright, and placing the sample rod into a refractory metal crucible and then assembling the refractory metal crucible to a directional solidification furnace; wherein the refractory metal crucible is prepared from molybdenum;
(3) vacuumizing the directional solidification furnace, introducing argon into the directional solidification furnace, turning on a high-frequency induction power supply and heating the directional solidification furnace raise a temperature of the directional solidification furnace to exceed a melting point of the sample rod, stopping heating, and conducting heat preservation to melt the sample rod uniformly, controlling a power of the directional solidification furnace, such that a temperature of a melting zone of the sample rod does not exceed the melting point of the sample rod by 50° C., and a length of the melting zone of the sample rod is no more than 15 mm, and the heat preservation is conducted for 30 min to 60 min to obtain a molten TiAl alloy; and
(4) directionally pulling the molten TiAl alloy after the heat preservation to allow directional growth, stopping the directionally pulling after reaching a growth length, cooling, introducing air, taking out an obtained sample, and removing a reaction layer on a surface of the obtained sample by machining to obtain a test rod of the directionally solidified TiAl alloy.

2. The method according to claim 1, wherein the TiAl alloy ingot in step (1) has a composition of (47-54)Ti-(45-48)Al-(1-5)Nb-(0-0.6)C.

3. The method according to claim 1, wherein the sample rod in step (2) has a dimension of Φ (5-50) mm×120 mm.

4. The method according to claim 1, wherein in step (3), the directional solidification furnace is vacuumized to 6×10⁻³ Pa by using a two-stage vacuum pump comprising a mechanical pump and a molecular pump, the two-stage vacuum pump is turned off, and then the argon is introduced into a cavity to 500 Pa.

5. The method according to claim 1, wherein in step (4), the directionally pulling is controlled at a speed of 10 μm/s to 160 μm/s by using a programmable logic controller (PLC) panel.

6. The method according to claim 1, wherein in step (4), a motor movement is stopped after the growth length reaches 120 mm, the high-frequency induction power supply is turned off, and the obtained sample is cooled to room temperature by furnace cooling.
